(19) United States
(12) Patent Application Publication
(10) Pub. No.: US 2025/0185388 A1
(43) Pub. Date: Jun. 5, 2025

(54) Graphene Photodetector

(71) Applicant: Nippon Telegraph and Telephone Corporation, Tokyo (JP)

(72) Inventors: Katsumasa Yoshioka, Musashino-shi, Tokyo (JP); Norio Kumada, Musashino-shi, Tokyo (JP); Masayuki Hashisaka, Musashino-shi, Tokyo (JP); Taro Wakamura, Musashino-shi, Tokyo (JP)

(21) Appl. No.: 18/841,284

(22) PCT Filed: Mar. 31, 2022
(86) PCT No.: PCT/JP2022/016933

§ 371 Date: Aug. 23, 2024

(51) Int. Cl. H10F 30/282; H10F 77/122; H10F 77/20

(52) U.S. Cl. CPC H10F 30/282; H10F 77/122; H10F 77/206

(57) ABSTRACT

A graphene photodetector of the present invention includes a gate electrode for controlling a Fermi level of graphene, wherein the gate electrode is made of ZnO. By providing the graphene photodetector of the present invention, an ultra-high-speed photodetector having a 3 dB bandwidth exceeding 200 GHz can be realized.

### TECHNICAL FIELD

The present invention relates to a graphene photodetector, and more particularly to a technique for improving the operating speed of the graphene photodetector.

### BACKGROUND ART

A graphene photodetector is an optical receiver capable of converting an optical signal into an electric signal at high speed and with high efficiency (NPL 1). In particular, since energy relaxation of photoexcited carriers generated when light is incident is relatively high, the graphene photodetector is expected to operate at a speed of 200 GHz or more in a 3 dB bandwidth.

### CITATION LIST

### Non Patent Literature

[NPL 1] M. Romagnoli, V. Sorianello, M. Midrio, F. H. L. Koppens, C. Huyghebaert, D. Neumaier, P. Galli, W. Templ, A. D'Errico, and A. C. Ferrari, Nat. Rev. (2018) Mater. 3, 392.
[NPL 2] J. W. McIver, B. Schulte, F.-U. Stein, T. Matsuyama, G. Jotzu, G. Meier, and A. Cavalleri, Nat. Phys. (2020) 16, 38.
[NPL 3] N. Kumada, N.-H. Tu, K.-i. Sasaki, T. Ota, M. Hashisaka, S. Sasaki, K. Onomitsu, and K. Muraki, Phys. Rev. (2020) B 101, 205205.
[NPL 4] N. H. Tu, K. Yoshioka, S. Sasaki, M. Takamura, K. Muraki, and N. Kumada, Commun. Mater. (2020) 1, 7.
[NPL 5] Z. Ma, K. Kikunaga, H. Wang, S. Sun, R. Amin, R. Maiti, M. H. Tahersima, H. Dalir, M. Miscuglio, and V. J. Sorger, ACS Photonics (2020) 7, 932.
[NPL 6] V. Miseikis, S. Marconi, M. A. Giambra, A. Montanaro, L. Martini, F. Fabbri, S. Pezzini, G. Piccinini, S. Forti, B. Terres, I. Goykhman, L. Hamidouche, P. Legagneux, V. Sorianello, A. C. Ferrari, F. H. L. Koppens, M. Romagnoli, and C. Coletti, ACS Nano (2020) 14, 11190.
[NPL 7] J. Li, C. Liu, H. Chen, J. Guo, M. Zhang, and D. Dai, Nanophotonics (2020) 9, 2295.
[NPL 8] M. Massicotte, G. Soavi, A. Principi, and K.-J. Tielrooij, Nanoscale (2021) 13, 8376.
[NPL 9] S. Marconi, M. A. Giambra, A. Montanaro, V. Miseikis, S. Soresi, S. Tirelli, P. Galli, F. Buchali, W. Templ, C. Coletti, V. Sorianello, and M. Romagnoli, Nat. Commun. (2021) 12, 806.

### SUMMARY OF INVENTION

### Technical Problem

However, since the response of graphene to light greatly changes depending on the Fermi level, it is necessary to form a gate structure for controlling the Fermi level, but this increases the RC time constant of the circuit and narrows the 3 dB bandwidth (NPL 2).

That is, in the conventional gate structure, a metal such as Au or graphite is used for the gate electrode. As a result, when a photocurrent generated in the graphene is extracted from a source/drain electrode, a gate capacitance C_{g} (capacitance formed between the gate electrode and the graphene film) is generated. In this case, regardless of the speed of the optical response of the graphene, the attenuation constant τ_{RC} of the photocurrent is given by the product of a circuit resistances R and C_{g} as shown in the following formula.

$$[ Math . 1 ]$$

$${τ}_{RC} = R \cdot {C}_{g} \qquad ( 1 )$$

As a result, the 3 dB bandwidth of the photodetector is rate-determined by a cut-off frequency f_{RC} of the following formula.

$$[ Math . 2 ]$$

$${f}_{RC} = \frac{1}{2 π \cdot {τ}_{RC}} \qquad ( 2 )$$

A typical value of τ_{RC} in formula (2) is 10 ps (NPL 2) in a micrometer-sized graphene photodetector. In this case, f_{RC} is 16 GHz, and a high speed of 200 GHz or more cannot be realized.

An object of the present invention is to provide a graphene photodetector which is not limited by a cutoff frequency f_{RC} of an electric circuit by disabling a gate capacitance C_{g}.

### Solution to Problem

One aspect of the graphene photodetector of the present invention is a graphene photodetector including a gate electrode for controlling a Fermi level of graphene, wherein the gate electrode is made of ZnO.

### Advantageous Effects of Invention

By using ZnO for the gate electrode, the RC time constant can be minimized, and a high-speed photodetector exceeding 200 GHz in a 3 dB bandwidth can be realized.

### BRIEF DESCRIPTION OF DRAWINGS

FIG. 1 is a diagram of a graphene photodetector according to Embodiment 1.

FIG. 2 is a diagram showing a frequency response of the graphene photodetector according to Embodiment 1.

FIG. 3 is a diagram of a graphene photodetector according to Embodiment 2.

FIG. 4 is a diagram of a graphene photodetector according to Embodiment 3.

FIG. 5 is a diagram of a graphene photodetector according to Embodiment 4.

FIG. 6 is a diagram of a graphene photodetector according to Embodiment 5.

FIG. 7 is a diagram of a graphene photodetector according to Embodiment 6.

FIG. 8 is a diagram of a graphene photodetector according to a comparative example.

FIG. 9 is a diagram showing a frequency response of the graphene photodetector according to the comparative example.

### DESCRIPTION OF EMBODIMENTS

Hereinafter, graphene photodetectors according to embodiments of the present invention will be described in detail with reference to the drawings. Note, however, that the present invention is not limited to the description of the embodiments below, and it is obvious for a person skilled in the art that the embodiments and details thereof may be modified in various manners without departing from the spirit of the inventions disclosed in the present specification and the like. Also, the configurations according to different embodiments can be implemented in appropriate combinations of one another. Note that, in the configurations of the invention described below, the same reference signs are given to the same components or components having similar functions, and the redundant description may be omitted.

### Embodiment 1

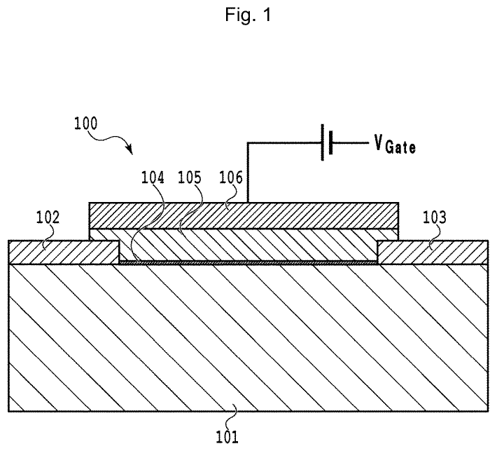

FIG. 1 is a cross-sectional view showing a top-gated graphene photodetector 100 according to Embodiment 1 of the present invention.

ZnO is used as the material of a gate electrode in which a metal is typically used. The Fermi level of graphene can be optimized by this gate structure.

The graphene photodetector 100 includes a substrate 101, a source electrode 102 and a drain electrode 103 formed on the substrate 101, and a graphene film 104 formed on the substrate 101, between the source electrode 102 and the drain electrode 103, so as to be in contact with these electrodes. Further, a ZnO layer 106 is formed above the graphene film 104 via an insulating layer 105.

As to the materials of the components of the graphene photodetector 100 of FIG. 1, examples of the material of the substrate 101 include Si, SiO₂ or Al₂O₃. The material for the source electrode 102 and the drain electrode 103 is, for example, a metallic material such as Ti/Au. The material of the insulating layer 105 is, for example, a material of an insulator such as Al₂O₃.

In the present specification, the ZnO layer is a layer composed of pure Zno. The ZnO layer may contain impurities. The ZnO layer may also not contain impurities. In the present specification, the graphene film is a layer consisting of pure graphene. The graphene film may contain impurities. The graphene film may also not contain impurities.

The Fermi level of the graphene is controlled by applying a voltage to the gate structure V_{Gate} described above. The ZnO has conductivity to a direct current, but has a lower conductivity in a region of GHz or higher, and becomes transparent to a high-frequency electromagnetic field (see NPLs 3, 4). Therefore, the gate electrode of the ZnO behaves as if it does not exist for a high-speed photocurrent while having a function of controlling the Fermi level of the graphene. As a result, the gate capacitance C_{g} can be minimized, and a high-speed graphene photodetector with a gate structure can be realized.

Although the value of the resistance R varies depending on the device to be mounted, in a case where the resistance R is set to 400Ω, for example, the gate capacitance C_{g} needs to be set to 7 fF or less in order to achieve a response of 200 GHz. In the present embodiment, as described above, by using ZnO for the gate electrode, the gate capacitance C_{g} can be set to 7 fF or less. When the resistance R increases, it is necessary to reduce the gate capacitance C_{g} inversely proportional to the resistance R.

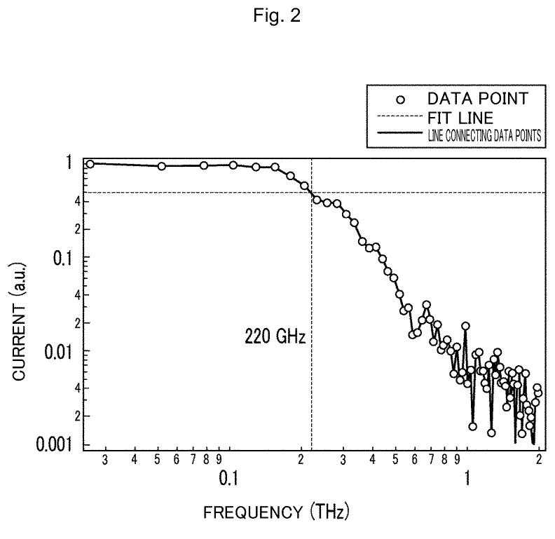

FIG. 2 shows a frequency response of the graphene photodetector 100 that is actually measured. The solid line represents data of vector network analysis (VNA), the white circles represent data of heterodyne, and a dashed line represents a fit line. Since the region cannot be measured by the conventional VNA, “the data is obtained by performing time-resolved measurement of the photocurrent with the time resolution of subpicosecond and performing Fourier transform on the time waveform. The white circles represent data points, the solid line represents a line connecting the data points, and the broken line represents a fit line. The 3 dB bandwidth reaches 220 GHz, and a high-speed photodetector determined by the original time response of the graphene can be realized.

By using ZnO for the gate electrode of the graphene photodetector, the RC time constant is minimized, and thereby the potential of the graphene can be maximized. As a result, an ultra-high-speed photodetector having a 3 dB bandwidth exceeding 200 GHZ can be realized.

Further, since the limitation on the device formation is not increased as compared with a normal metal electrode when ZnO is used as a gate electrode, various applications are possible.

### Embodiment 2

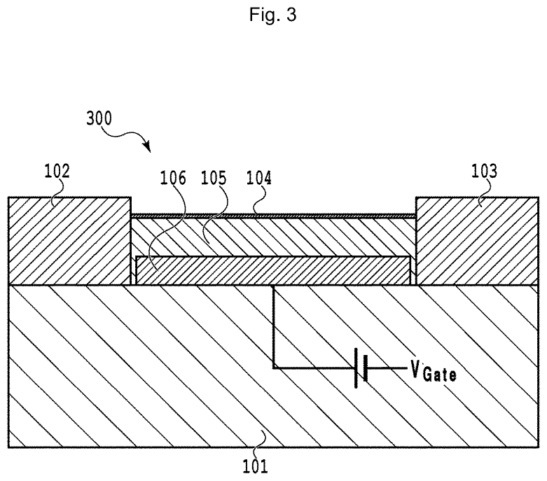

Although Embodiment 1 has illustrated an example of a top gate structure, Embodiment 2 describes a graphene photodetector 300 having a bottom gate structure with reference to FIG. 3.

The graphene photodetector 300 includes a substrate 101, a source electrode 102 and a drain electrode 103 on the substrate 101, a ZnO layer 106 formed on the substrate 101, between the source electrode 102 and the drain electrode 103, an insulating layer 105 on the ZnO layer 106, the source electrode 102 and the drain electrode 103, and a graphene film 104 on the insulating layer 105. The height of an upper surface of the insulating layer 105 is lower than the film thickness of the source electrode 102 and the drain electrode 103. The graphene film 104 is formed between the source electrode 102 and the drain electrode 103 so as to be in contact with these electrodes.

By using ZnO for the gate electrode of the graphene photodetector of Embodiment 2, the RC time constant can be minimized, and thereby the potential of the graphene can be maximized. As a result, an ultra-high-speed photodetector having a 3 dB bandwidth exceeding 200 GHz can be realized.

### Embodiment 3

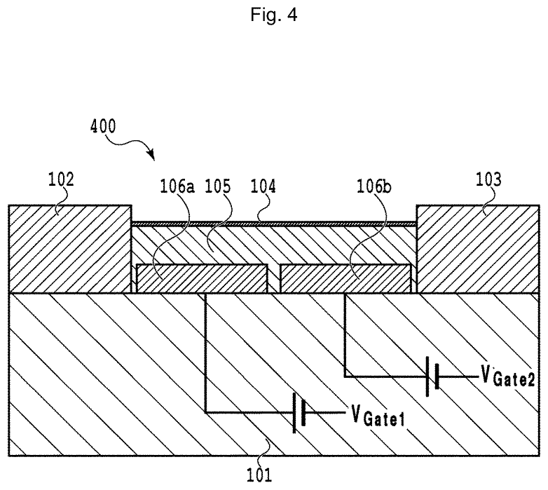

Although Embodiment 2 has illustrated an example of a top gate structure, this embodiment describes a graphene photodetector 400 having a dual gate structure with reference to FIG. 4. The graphene photodetector 300 has a single ZnO layer 106, whereas the graphene photodetector 400 has a plurality of ZnO layers 106a, 106b.

By using ZnO for the gate electrode of the graphene photodetector of Embodiment 3, the RC time constant can be minimized, and thereby the potential of the graphene can be maximized. As a result, an ultra-high-speed photodetector having a 3 dB bandwidth exceeding 200 GHz can be realized.

### Embodiment 4

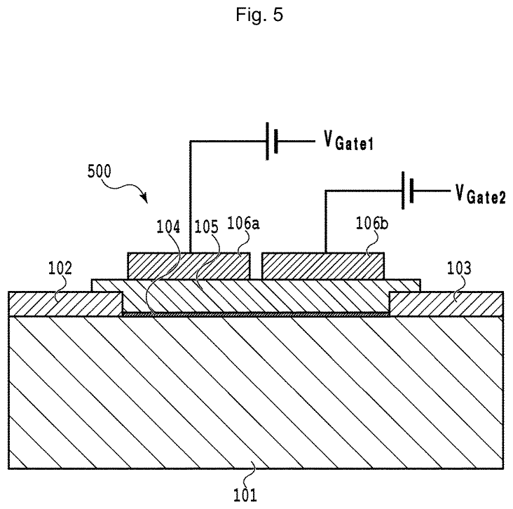

Although Embodiment 1 has illustrated an example of a top gate structure, this embodiment describes a graphene photodetector 500 having a dual gate structure with reference to FIG. 5. The graphene photodetector 100 has a single ZnO layer 106, whereas the graphene photodetector 500 has a plurality of ZnO layers 106a, 106b.

By using ZnO for the gate electrode of the graphene photodetector of Embodiment 4, the RC time constant can be minimized, and thereby the potential of the graphene can be maximized. As a result, an ultra-high-speed photodetector having a 3 dB bandwidth exceeding 200 GHz can be realized.

### Embodiment 5

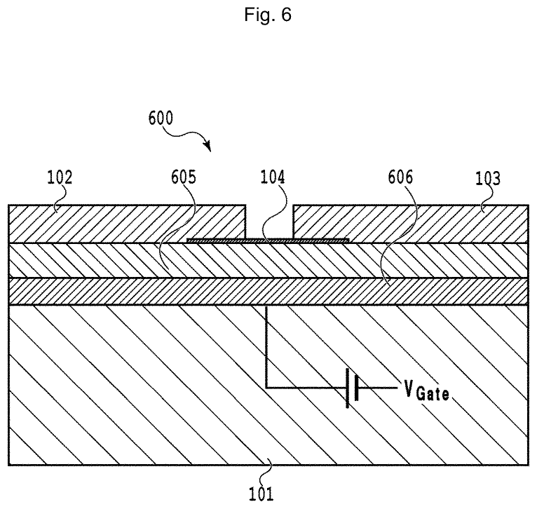

Although Embodiment 1 has illustrated an example in which the insulating layer 105 and the ZnO layer 106 are patterned, this embodiment describes a graphene photodetector 600 shown in FIG. 6 in which an insulating layer 605 and a ZnO layer 606 are not patterned. The source electrode 102 and the drain electrode 103 are formed so as to cover both ends of the graphene film 104.

Further, Au is adopted as the material of the source electrode 102 and the drain electrode 103, and a metal-dielectric-metal (Metal Insulator Metal; MIM) waveguide constituted of a nano-gap between the source electrode 102 and the drain electrode 103 is formed. (NPL 5)

By using ZnO for the gate electrode of the graphene photodetector of Embodiment 5, the RC time constant can be minimized, and thereby the potential of the graphene can be maximized. As a result, an ultra-high-speed photodetector having a 3 dB bandwidth exceeding 200 GHz can be realized.

### Embodiment 6

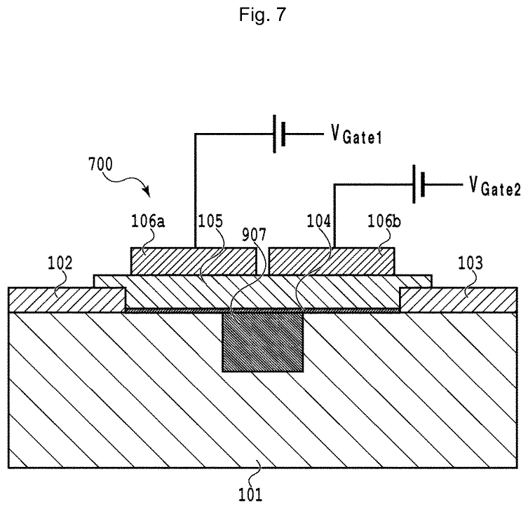

In Embodiment 6, FIG. 7 shows a graphene photodetector 700 having a top dual gate structure in which an Si or Si₃N₄ waveguide 907 is combined with a recess on a substrate 101. A graphene film 104 is formed on the Si or Si₃N₄ waveguide 907. (NPLs 6, 9)

By using ZnO for the gate electrode of the graphene photodetector of Embodiment 6, the RC time constant can be minimized, and thereby the potential of the graphene can be maximized. As a result, an ultra-high-speed photodetector having a 3 dB bandwidth exceeding 200 GHz can be realized.

The Si or Si₃N₄ waveguide 907 according to Embodiment 6 may be combined with the recess on the substrate 101 of the photodetector 100 having the top gate structure according to Embodiment 1.

In various structures disclosed so far, for example, in a hybrid silicon optical response device, the 3 dB bandwidth of the graphene photodetector can be widened to the limit by replacing the gate electrode with ZnO and disabling the gate capacitance C_{g}. (NPLs 7, 8)

In the present invention, ZnO is employed as the gate electrode, but the present invention is not limited thereto; instead, it is possible to use a transparent material that has conductivity to a DC electric field in principle but has no conductivity in a 3 dB bandwidth range of GHz to THz.

Since it is only necessary to change the material of the gate electrode to ZnO, the application range is very wide, and the present invention is applicable to various structures.

### Comparative Example 1

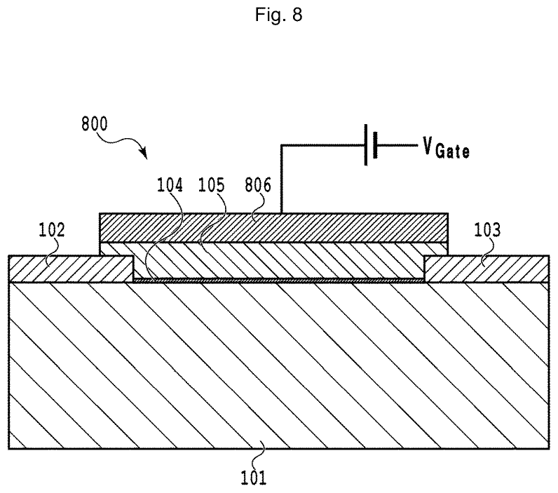

A conventional graphene photodetector 800 will be described with reference to FIG. 8. A gate electrode 806 is made of a metallic material such as Au or graphite. The materials of the other components shown in FIG. 8 are the same as those of the components shown in FIG. 1.

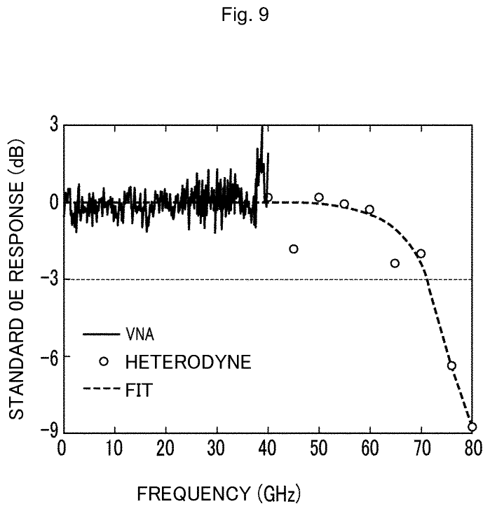

FIG. 9 shows a frequency response of the conventional graphene photodetector 800. The solid line represents data of vector network analysis (VNA), the white circles represent data of heterodyne, and a dashed line represents a fit line. As a result, it can be seen that the maximum value of the 3 dB bandwidth, which has been experimentally reported, remains at 70 GHz in the graphene photodetector having the gate electrode 806 (NPL 9).

1. A graphene photodetector, comprising a gate electrode for controlling a Fermi level of graphene, wherein the gate electrode is made of ZnO.

2. The graphene photodetector according to claim 1, wherein the gate electrode is provided on a layer made of the graphene, via an insulating layer.

3. The graphene photodetector according to claim 1, further comprising a layer made of the graphene on the gate electrode, via an insulating layer.

4. The graphene photodetector according to claim 1, wherein the ZnO is composed of a plurality of layers.

5. The graphene photodetector according to claim 2, wherein the insulating layer and the gate electrode are patterned.

6. The graphene photodetector according to claim 2, wherein the insulating layer and the gate electrode are not patterned.

7. The graphene photodetector according claim 2, wherein an Si waveguide or an Si3N4 waveguide is provided on a substrate, and the layer made of the graphene is provided on the waveguide.

8. The graphene photodetector according to claim 1, wherein a film made of the graphene is in contact with the source electrode and the drain electrode.
